(19) United States
(12) Patent Application Publication
(10) Pub. No.: US 2023/0232680 A1
(43) Pub. Date: Jul. 20, 2023

(54) DISPLAY APPARATUS

(71) Applicant: Samsung Display Co., Ltd., Yongin-si (KR)

(72) Inventors: Dongchul Shin, Yongin-si (KR); Seongwon Kim, Yongin-si (KR); Inseon Yoon, Yongin-si (KR)

(21) Appl. No.: 18/097,006

(22) Filed: Jan. 13, 2023

(30) Foreign Application Priority Data
Jan. 17, 2022 (KR) 10-2022-0006799

(51) Int. Cl. H10K 59/131; H10K 59/80

(52) U.S. Cl. CPC H10K 59/131; H10K 59/873

(57) ABSTRACT

A display apparatus includes a substrate, a first display unit, a second display unit, a conductive wire, and an insulating material member set. The substrate includes a first island, a connection unit, a second island spaced from the first island and connected through the connection unit to the first island, and an opening positioned between the connection unit and the first island. The first display unit overlaps the first islands. The second display unit overlaps the second island. The conductive wire overlaps the connection unit. The insulating material member set overlaps an edge region of the connection unit, is positioned closer to or farther from the connection unit than the conductive wire, and is spaced from the conductive wire in a plan view of the display apparatus.

### CROSS-REFERENCE TO RELATED APPLICATION

This application claims priority under 35 U.S.C. § 119 to Korean Patent Application No. 10-2022-0006799 filed on Jan. 17, 2022 in the Korean Intellectual Property Office; the Korean Patent Application is incorporated by reference.

### BACKGROUND

### 1. Field

The technical field is related to a display apparatus.

### 2. Description of the Related Art

A display apparatus may display image in response to input signals. Various display apparatuses may be included in various electronic devices and may have various characteristics, such as a slim profile, light weight, low power consumption, and/or flexibility.

### SUMMARY

One or more embodiments may be related to a flexible display apparatus such as a stretchable display apparatus.

According to one or more embodiments, a display apparatus includes a substrate including a plurality of islands spaced apart from one another, a connection unit connecting the plurality of islands to one another, and a plurality of openings between the plurality of islands, a plurality of unit display units on the plurality of islands, respectively, wires on the connection unit, and a pattern layer disposed on a different layer from a layer on which the wires are located on the connection unit, the pattern layer being arranged on an edge of the connection unit.

The pattern layer may include an inorganic insulating material.

The display apparatus may further include an organic material layer disposed between the pattern layer and the wires.

A buffer layer, a gate insulating layer, a first interlayer insulating layer, and a second interlayer insulating layer each including an inorganic insulating material may be disposed on the plurality of islands, and the pattern layer may include the same material as a material included in at least one of the buffer layer, the gate insulating layer, the first interlayer insulating layer, and the second interlayer insulating layer.

The pattern layer may overlap a center of a longer side of the connection unit in a plan view.

The pattern layer may include a plurality of sub-patterns, and the plurality of sub-patterns may be arranged apart from one another along the edge of the connection unit.

A width of each of the plurality of sub-patterns may increase from the edge of the connection unit to inside the connection unit.

The plurality of sub-patterns may be connected to one another near the wires.

The display apparatus may further include an encapsulation layer configured to encapsulate the plurality of unit display units.

The encapsulation layer may include an organic encapsulation layer, a first inorganic encapsulation layer below the organic encapsulation layer, and a second inorganic encapsulation layer above the organic encapsulation layer, the organic encapsulation layer may include unit organic encapsulation layers corresponding to the plurality of unit display units, respectively, and the first inorganic encapsulation layer and the second inorganic encapsulation layer may contact each other outside the unit organic encapsulation layers.

The first inorganic encapsulation layer and the second inorganic encapsulation layer may contact each other on the connection unit.

The first inorganic encapsulation layer and the second inorganic encapsulation layer may include a recess pattern on the edge of the connection unit.

The recess pattern may include a plurality of sub-recesses spaced apart from each other along the edge of the connection unit.

According to one or more embodiments, a display apparatus includes a substrate including a plurality of islands spaced apart from one another, a connection unit connecting the plurality of islands to one another, and a plurality of openings between the plurality of islands, a plurality of unit display units on the plurality of islands, respectively, an encapsulation layer configured to seal each of the plurality of unit display units, and including a first inorganic encapsulation layer, an organic encapsulation layer, and a second inorganic encapsulation layer, and wires on the connection unit. The first inorganic encapsulation layer and the second inorganic encapsulation layer contact each other on the connection unit, and include a recess pattern arranged on the edge of the connection unit.

The recess pattern may include a plurality of sub-recesses spaced apart from each other along the edge of the connection unit.

The display apparatus may further include an organic material layer disposed between the substrate and the wires on the connection unit.

The organic encapsulation layer may include unit organic encapsulation layers corresponding to the plurality of unit display units, respectively, and the first inorganic encapsulation layer and the second inorganic encapsulation layer may contact each other outside the unit organic encapsulation layers.

The first inorganic encapsulation layer and the second inorganic encapsulation layer may be at least partially arranged on lateral surfaces of the plurality of openings.

The display apparatus may further include a pattern layer on a different layer from a layer on which the wires are located on the connection unit, the pattern layer being arranged on the edge of the connection unit.

The pattern layer may include an inorganic insulating material.

The recess pattern may overlap the pattern layer.

An embodiment may be related to a display apparatus. The display apparatus may include a substrate, a first display unit, a second display unit, a conductive wire, and an insulating material member set. The substrate may include a first island, a connection unit, a second island spaced from the first island and connected through the connection unit to the first island, and an opening positioned between the connection unit and the first island. The first display unit may overlap the first islands. The second display unit may overlap the second island. The conductive wire may overlap the connection unit. The insulating material member set may overlap an edge region of the connection unit, may be positioned closer to or farther from the connection unit than the conductive wire, and may be spaced from the conductive wire in a plan view of the display apparatus.

The insulating material member set may include an inorganic insulating material.

The display apparatus may further include an organic material layer disposed between the insulating material member set and the conductive wire.

The display apparatus may further include a buffer layer, a gate insulating layer, a first interlayer insulating layer, and a second interlayer insulating layer each including an inorganic insulating material and disposed on the first island. A material of the insulating material member set may be identical to a material of at least one of the buffer layer, the gate insulating layer, the first interlayer insulating layer, and the second interlayer insulating layer.

A first side of the connection unit may be longer than a second side of the connection unit. The insulating material member set may overlap a geometric center line of the connection unit that cross the first side of the connection unit in the plan view of the display apparatus.

The insulating material member set may include insulating material members that are spaced from one another in a lengthwise direction of the connection unit.

The insulating material members may include a first insulating material member. A first edge of the first insulating material member may be longer than a second edge of the first insulating material member, opposite the second edge of the first insulating material member, and positioned between the conductive wire and the second edge of the first insulating material member in the plan view of the display apparatus.

The insulating material member set may include an insulating material part, wherein two of the insulating material members may be connected through the insulating material part to each other. A space may be positioned between the two of the insulating material members. The insulating material part may be positioned between the conductive wire and the space.

The display apparatus may further include an encapsulation layer that covers the first display unit. The encapsulation layer may include an organic encapsulation layer, a first inorganic encapsulation layer, and a second inorganic encapsulation layer. The organic encapsulation layer may be positioned between the first inorganic encapsulation layer and the second inorganic encapsulation layer and may be spaced from the connection unit by at least one of the first inorganic encapsulation layer and the second inorganic encapsulation layer. The first inorganic encapsulation layer and the second inorganic encapsulation layer may directly contact each other outside the organic encapsulation layer.

The first inorganic encapsulation layer and the second inorganic encapsulation layer may directly contact each other on/over the connection unit.

The first inorganic encapsulation layer and the second inorganic encapsulation layer may include a recess set that overlaps with the edge region of the connection unit.

The recess set may include recesses that are spaced from each other in a lengthwise direction of the connection unit.

An embodiment may be related to a display apparatus. The display apparatus may include the following elements: a substrate including a first island, a connection unit, a second island spaced from the first island and connected through the connection unit to the first island, and an opening positioned between the connection unit and the first island; a first display unit overlapping the first island; a second display unit overlapping the second island; an encapsulation layer covering the first display unit and may include a first inorganic encapsulation layer, an organic encapsulation layer, and a second inorganic encapsulation layer; and a conductive wire overlapping the connection unit. The first inorganic encapsulation layer and the second inorganic encapsulation layer may directly contact each other on/over the connection unit and may include a recess set. The recess set may overlap with an edge region of the connection unit and may be spaced from the conductive wire in a plan view of the display apparatus.

The recess set may include recesses that are spaced from each other in a lengthwise direction of the connection unit.

The display apparatus may further include an organic material layer disposed between the conductive wire and the connection unit.

The organic encapsulation layer may overlap the first display unit and may be spaced from the connection unit by at least one of the first inorganic encapsulation layer and the second inorganic encapsulation layer. The first inorganic encapsulation layer and the second inorganic encapsulation layer may directly contact each other outside the organic encapsulation layer.

The first inorganic encapsulation layer and the second inorganic encapsulation layer may directly contact lateral surfaces/walls of the opening.

The display apparatus may further include an insulating material member set. The insulating material member set may be positioned closer to or farther from the connection unit than the conductive wire, may overlap the edge region of the connection unit, and may be spaced from the conductive wire in the plan view of the display apparatus.

The insulating material member set may include an inorganic insulating material.

The recess set may overlap with the insulating material member set.

### BRIEF DESCRIPTION OF THE DRAWINGS

FIG. 1 is a schematic plan view of (a portion of) a display apparatus according to an embodiment.

FIG. 2A is a schematic perspective view of (a portion of) a display apparatus according to an embodiment.

FIG. 2B is a schematic plan view of (a portion of) a display apparatus stretched according to an embodiment.

FIG. 3 is a schematic plan view of a display unit of FIG. 1 according to an embodiment.

FIG. 4 is a schematic cross-sectional view taken along line I-I′ of FIG. 3 according to an embodiment.

FIG. 5 is a schematic plan view of a connection unit according to an embodiment.

FIG. 6 is a schematic plan view of a connection unit according to an embodiment.

FIG. 7 is a schematic plan view of a connection unit according to an embodiment.

FIG. 8 is a schematic plan view of a connection unit according to an embodiment.

FIG. 9 is a schematic cross-sectional view of a display apparatus according to an embodiment.

FIG. 10 is a schematic plan view of a connection unit according to an embodiment.

FIG. 11 is a schematic cross-sectional view of a display apparatus according to an embodiment.

### DETAILED DESCRIPTION

Examples of embodiments are described with reference to the accompanying drawings, wherein like reference numerals may refer to like elements. Practical embodiments may have different forms and should not be construed as being limited to the described embodiments.

Although the terms “first,” “second,” etc. may be used to describe various elements/features, these elements/features should not be limited by these terms. These terms may be used to distinguish one element/feature from another. A first element may be termed a second element without departing from teachings of one or more embodiments. The description of an element as a “first” element may not require or imply the presence of a second element or other elements. The terms “first,” “second,” etc. may be used to differentiate different categories or sets of elements. For conciseness, the terms “first,” “second,” etc. may represent “first-category (or first-set),” “second-category (or second-set),” etc., respectively.

The singular forms “a,” “an,” and “the” may indicate the plural forms as well, unless the context clearly indicates otherwise.

The terms “comprise” and/or “comprising” may specify the presence of stated features or components, but may not preclude the presence or addition of one or more other features or components.

Dimensions of elements illustrated in the drawings may be exaggerated for convenience of explanation. Embodiments of the disclosure are not limited to the illustrated dimensions.

When a certain embodiment may be implemented differently, a specific process order may be performed differently from the described order. For example, two consecutively described processes may be performed substantially at the same time or performed in an order opposite to the described order.

The term “on” may mean “directly on” or “indirectly on.” The term “connect” may mean “directly connect” or “indirectly connect.” The term “connect” may mean “mechanically connect” and/or “electrically connect.” The term “connected” may mean “electrically connected” or “electrically connected through no intervening transistor.” The term “insulate” may mean “electrically insulate” or “electrically isolate.” The term “conductive” may mean “electrically conductive.” The term “drive” may mean “operate” or “control.” The term “include” may mean “be made of.” The term “adjacent” may mean “immediately adjacent.” The term “contact” may mean “directly contact.” The expression that an element extends in a particular direction may mean that the element extends lengthwise in the particular direction and/or that the lengthwise direction of the element is in the particular direction. The term “pattern” may mean “member.” The term “defined” may mean “formed” or “provided.” The expression that a space or opening overlaps an object may mean that (the position of) the space or opening overlaps with (the position of) the object. The term “overlap” may be equivalent to “be overlapped by.” The expression that a first element overlaps with a second element in a plan view may mean that the first element overlaps the second element in direction perpendicular to a substrate.

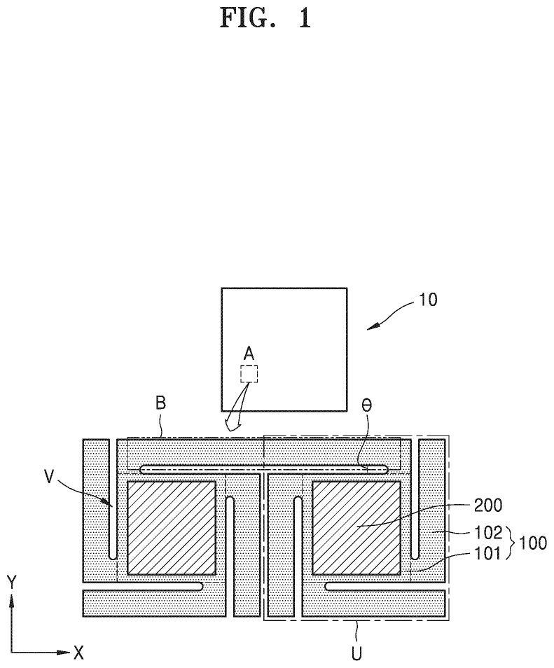

FIG. 1 is a schematic plan view of (a portion A of) a display apparatus 10 according to an embodiment.

Referring to FIG. 1, the display apparatus 10 may include a substrate 100 and display units 200 on the substrate 100.

The substrate 100 may include glass, metal, or an organic material.

The substrate 100 may include a flexible material, which may be easily bent, folded, and/or rolled. The flexible material may be ultra-thin glass, metal, or plastic. The substrate 100 may contain polyimide (PI) and/or another type of plastic material.

The substrate 100 may include islands 101 spaced apart from one another, connection units 102 connecting the islands 101 to one another, and openings V penetrating through the substrate 100 and positioned between the connection units 102 and the islands 101.

The islands 101 may be spaced from one another. The islands 101 may be arranged in a first direction X and a second direction Y different from the first direction X in a two-dimensional array. The first direction X and the second direction Y may be perpendicular to each other. The first direction X and the second direction Y may be oblique relative to each other.

The display units 200 may be arranged on the islands 101, respectively. Each display unit 200 may include at least one display element configured to emit visible light.

The connection units 102 may connect the islands 101 to one another. Four connection units 102 may be directly connected to each of the islands 101, may extend/protrude from the island 101 in different directions, and may be respectively connected to other islands 101 surrounding the island 101. The islands 101 and the connection units 102 may include one or more same materials. The islands 101 and the connection units 102 may be integrally formed with each other. The openings V may be arranged between the islands 101 and the connection units 102.

The openings V penetrate through the substrate 100. The openings V may provide separations between the islands 101, may reduce the weight of the substrate 100, and may improve the flexibility of the substrate 100. When the substrate 100 is bent, rolled, or the like, the shapes of the openings V change, and thus stress during deformation of the substrate 100 may be mitigated. Thus, abnormal deformation of the substrate 100 may be prevented, and durability of the substrate 100 may be satisfactory. The display apparatus 10 may be applied to wearable devices.

The openings V may be formed by partially removing the substrate 100 via etching and/or a different process during the manufacture of the substrate 100.

A unit U of the substrate 100 may include an island 101 and at least one connection unit 102 connected to the island 101. Units U may be arranged in the first direction X and the second direction Y. Four connection units 102 may be connected to one island 101.

The islands 101 of two adjacent units U may be spaced from each other, and connection units 102 of the two adjacent units U may be directly connected to each other. A connection unit 102 may be referred to as a partial region of the connection unit 102 that is located within the unit U or may be referred to as the whole of a connection unit 102 that connects the two adjacent islands 101 to each other.

An opening V may be an empty space arranged between adjacent units U. The opening V is formed by partially removing the substrate 100, may improve the flexibility of the substrate 100, and may reduce stress when the substrate 100 is bent or stretched.

Two adjacent units U among the units U may be mirror images to each other. Referring to FIG. 1, one unit U may be a mirror image to an adjacent unit U in the first direction X, about an axis of symmetry extending in the second direction Y.

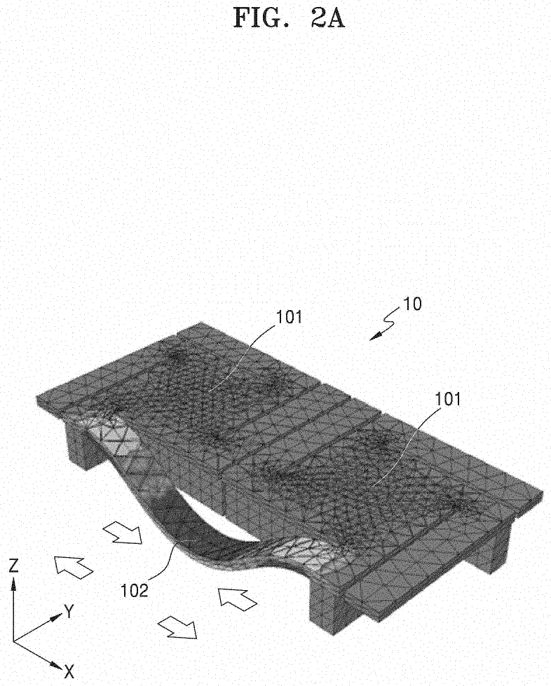

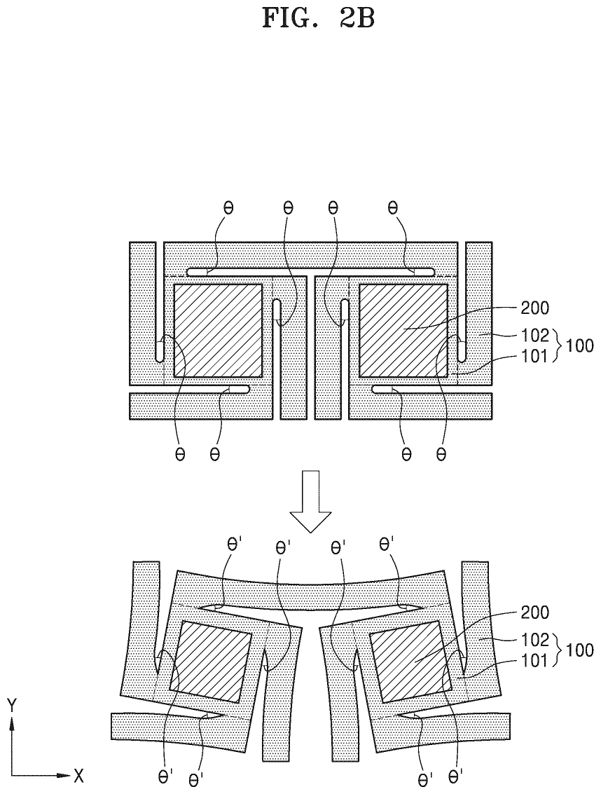

FIG. 2A illustrates a schematic perspective view of the substrate 100 of the display apparatus 10 when the substrate 100 is deformed in a third direction Z.

Referring to FIG. 2A, when a tensile force or a contractile force is applied to the substrate 100, the connection unit 102 may be bent, and one portion of the connection unit 102 may move in a third direction (Z or −Z direction). A distance between adjacent islands 101 may increase or decrease, and the display apparatus 10 may be deformed. The connection unit 102 may be bent in the third direction, and the display apparatus 10 may be stretched. stretching of the display apparatus 10 in the first direction X and stretching of the display apparatus 10 in the second direction Y may be independently performed.

FIG. 2B illustrates a plan view of a portion of the substrate 100 stretched in the first direction X and the second direction Y.

Referring to FIG. 2B, when an external force is applied to the substrate 100, all of the angles θ formed by the connection units 102 and the lateral surfaces of the islands 101 to which the connection units 102 are connected increase (θ<θ′), and thus the areas of the openings V may enlarge. Accordingly, spaces between the islands 101 may increase, and thus the substrate 100 may be stretched both in the first direction X and the second direction Y and thus the shape of the substrate 100 may change two-dimensionally and/or three-dimensionally.

Since each connection unit 102 has a smaller width than each island 101, a shape change related to the angle increase when an external force is applied to the substrate 100 may mainly occur in the connection units 102, and the shapes of the islands 101 may not substantially change even when the substrate 100 is stretched. Thus, the display units 200 arranged on the islands 101 may be not be significantly deformed even when the substrate 100 is stretched. Therefore, the display apparatus 10 may be a flexible display apparatus such as a bendable display apparatus and/or stretchable display apparatus with satisfactory performance, reliability, and/or durability.

Because stress concentrates on connecting portions of the connection units 102 connected to the lateral surfaces of the islands 101 during stretching of the substrate 100, the connecting portions of the connection units 102 may include/form curved surfaces in order to prevent tearing or the like of the connection units 102 due to the concentration of the stress.

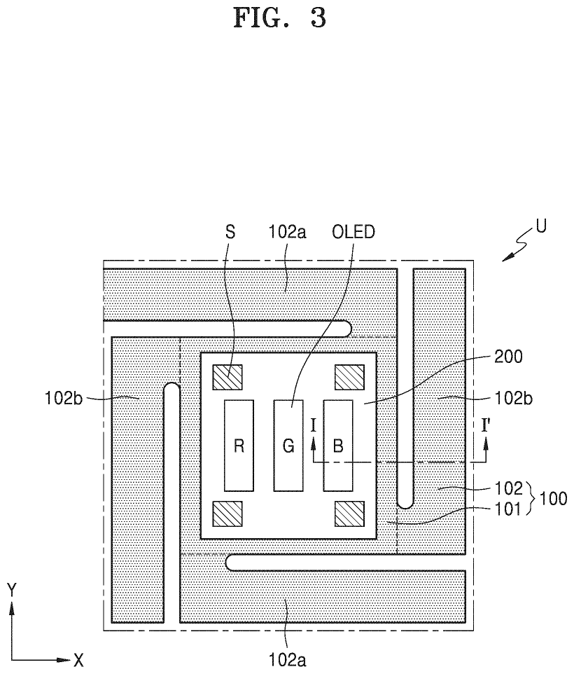

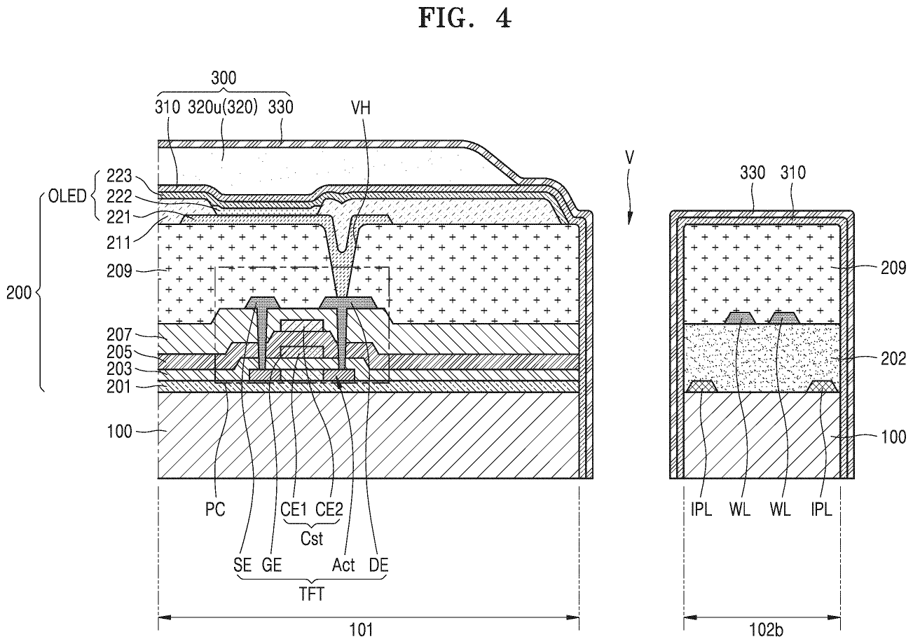

FIG. 3 is a plan view of a unit U illustrated in FIG. 1 according to an embodiment. FIG. 4 is a schematic cross-sectional view of a cross-section taken along line I-I′ of FIG. 3.

Referring to FIGS. 3 and 4, a display unit 200 and an encapsulation layer 300 encapsulating the display unit 200 may be located on an island 101 of the unit U. The corresponding connection units 102 may include a pair of first connection units 102a located at opposite sides of the island 101, respectively, and each extending in the first direction X, and may include a pair of second connection units 102b located at opposite sides of the island 101, respectively, and each extending in the second direction Y.

The display unit 200 may be located on the island 101, and at least one organic light-emitting diode OLED emitting red, blue, green, or white light may be included in the display unit 200 and may be electrically connected to a thin-film transistor TFT. An organic light-emitting diode OLED may be a display element included in the display unit 200. The display unit 200 may include one or more other types of display elements, such as an inorganic EL device, a quantum dot light-emitting device, and/or a liquid crystal display.

Each display unit 200 may include organic light-emitting diodes OLED that emit different lights. For example, as shown in FIG. 3, one display unit 200 of one pixel may include an organic light-emitting diode OLED emitting red (R) light, an organic light-emitting diode OLED emitting green (G) light, and an organic light-emitting diode OLED emitting blue (B) light.

Each display unit 200 may include one organic light-emitting diode OLED emitting red (R), blue (B), green (G), or white (W) light, and thus may form a sub-pixel. One display unit 200 may include multiple sub-pixels.

Organic light-emitting diodes OLED within the display unit 200 may be arranged in a configuration, such as an RGB configuration, a PENTILE® structure, or a honeycomb structure, according to the efficiency of a material included in an organic emission layer.

A spacer S may be formed on the periphery of the display unit 200. The spacer S may prevent damage to the display unit 200 by a mask. The spacer S may have a greater height (from an upper surface of the substrate 100) than the organic light-emitting diode OLED. FIG. 3 illustrates that the spacers S are provided at corner portions of the display unit 200. The spacers S may be arranged inside the display unit 200. The spacers S may be provided on a pixel defining layer 211 formed in the display unit 200.

Referring to FIG. 4, the display apparatus includes the substrate 100, the display unit 200 (including a portion of a planarization layer 209), and an encapsulation layer 300 covering the display unit 200. The display unit 200 may be disposed on the corresponding island 101 of the substrate 100. Wires WL may be arranged on a connection unit 102b that connects islands 101.

A buffer layer 201 is formed on the island 101 to prevent infiltration of impurities into a semiconductor layer Act of the thin-film transistor TFT. The buffer layer 201 may include an inorganic insulating material such as silicon oxide, silicon nitride, or silicon oxynitride, and may be a single layer or multiple layers including the inorganic insulating material.

A pixel circuit PC may be disposed on the buffer layer 201. The pixel circuit PC includes a thin-film transistor TFT and a storage capacitor Cst. The thin-film transistor TFT may include the semiconductor layer Act, a gate electrode GE, a source electrode SE, and a drain electrode DE. The thin-film transistor TFT may be a top gate type in which the gate electrode GE is arranged on the semiconductor layer Act and is insulated from the semiconductor layer Act by a gate insulating layer 203. The thin-film transistor TFT may be a bottom gate type.

The semiconductor layer Act may include polysilicon. The semiconductor layer Act may include amorphous silicon, an oxide semiconductor, or an organic semiconductor. The gate electrode GE may include a low resistance metal material. The gate electrode GE may include a conductive material including molybdenum (Mo), aluminum (Al), copper (Cu), and/or titanium (Ti), and may be a single layer or multi-layer structure.

The gate insulating layer 203 between the semiconductor layer Act and the gate electrode GE may include an inorganic insulating material such as silicon oxide, silicon nitride, silicon oxynitride, aluminum oxide, titanium oxide, tantalum oxide, or hafnium oxide. The gate insulating layer 203 may be a single layer or multi-layer structure.

The source electrode SE and the drain electrode DE may include a highly conductive material. Each of the source electrode SE and the drain electrode DE may include a conductive material including Mo, Al, Cu, and/or Ti, and may be a single layer or multi-layer structure. Each of the source electrode SE and the drain electrode DE may be a multi-layer structure of Ti/Al/Ti.

The storage capacitor Cst may include a lower electrode CE1 and an upper electrode CE2 overlapping each other and insulated from each other by a first interlayer insulating layer 205. The storage capacitor Cst and the thin-film transistor TFT may overlap each other. FIG. 4 illustrates that the gate electrode GE of the thin-film transistor TFT is the lower electrode CE1 of the storage capacitor Cst. The storage capacitor Cst and the thin-film transistor TFT may not overlap each other. The storage capacitor Cst may be covered by a second interlayer insulating layer 207.

The first and second interlayer insulating layers 205 and 207 may include an inorganic insulating material, such as silicon oxide, silicon nitride, silicon oxynitride, aluminum oxide, titanium oxide, tantalum oxide, or hafnium oxide. Each of the first and second interlayer insulating layers 205 and 207 may be a single layer or multi-layer structure.

The pixel circuit PC including the thin-film transistor TFT and the storage capacitor Cst may be covered by the planarization layer 209.

The planarization layer 209 may include an organic insulating material, such as a commercial polymer (such as polymethyl methacrylate (PMMA) or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend of some of the above polymers. The planarization layer 209 may include polyimide.

The planarization layer 209 may include an inorganic insulating material, such as silicon oxide, silicon nitride, silicon oxynitride, aluminum oxide, titanium oxide, tantalum oxide, or hafnium oxide. The planarization layer 209 may have a structure in which an organic insulating layer and an inorganic insulating layer are stacked.

To form the planarization layer 209, after a liquid organic material is coated to cover the thin-film transistor TFT, a mask process and a development process may be performed to form a via hole VH exposing the drain electrode DE of the thin-film transistor TFT. The planarization layer 209 is formed by curing the liquid organic material and thus may have a substantially flat upper surface.

A pixel electrode 221 may be formed on the planarization layer 209. The pixel electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 221 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound or alloy of some of these materials. The pixel electrode 221 may include a layer formed of ITO, IZO, ZnO, or In₂O₃ over/under the aforementioned reflection layer.

The pixel defining layer 211 may be formed on the pixel electrode 221. The pixel defining layer 211 may include an opening that exposes an upper surface of the pixel electrode 221 and may cover an edge of the pixel electrode 221. Accordingly, the pixel defining layer 211 may define a light-emission region of a pixel. The pixel defining layer 211 may include an organic insulating material. The pixel defining layer 211 may include an inorganic insulating material, such as silicon nitride (SiNₓ), silicon oxynitride (SiOₓN_{y}), or silicon oxide (SiOₓ). The pixel defining layer 211 may include an organic insulating material and an inorganic insulating material.

An intermediate layer 222 of the organic light-emitting diode OLED may include a low molecular weight material or a high molecular weight material. When the intermediate layer 220 includes a low molecular weight material, the intermediate layer 220 may be formed by stacking a hole injection layer (HIL), a hole transport layer (HTL), an emission layer (EML), an electron transport layer (ETL), and an electron injection layer (EIL) in a single structure or a composite structure, and may include material(s) such as copper phthalocyanine (CuPc), N,N′-Di(naphthalene-1-yl)-N,N′-diphenyl-benzidine (NPB), and/or tris(8-hydroxyquinoline) aluminum (Alq₃). These layers may be formed via vacuum deposition.

When the intermediate layer 222 includes a high-molecular weight material, the intermediate layer 222 may include a hole transport layer (HTL) and an emission layer (EML). The hole transport layer may include poly(3,4-ethylenedioxythiophene) (PEDOT), and the emission layer may include a high-molecular weight material such as a polyphenylene vinylene (PPV)-based material or a polyfluorene-based material. The intermediate layer 222 may be formed via screen printing, inkjet printing, laser induced thermal imaging (LITI), or the like.

The intermediate layer 222 may have one or more other structures. The intermediate layer 222 may include a single layer that covers a plurality of pixel electrodes 221 or may include patterned layers respectively corresponding to pixel electrodes 221.

An opposite electrode 223 may include a conductive material having a low work function. The opposite electrode 223 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of some of these materials. The opposite electrode 223 may further include a layer of ITO, IZO, ZnO, or In₂O₃ on the (semi)transparent layer. The opposite electrode 223 may be formed not only on the island 101 but also on the connection units 102. The intermediate layer 222 and the opposite electrode 223 may be formed via thermal deposition.

A capping layer (not shown) may be further disposed on the opposite electrode 223 to protect the opposite electrode 223. The capping layer may include an inorganic material such as lithium fluoride (LiF), and/or an organic material.

The encapsulation layer 300 sealing the display unit 200 is formed on the opposite electrode 223. The encapsulation layer 300 may block external oxygen and external moisture and may include a single layer or a plurality of layers. The encapsulation layer 300 may include at least one of an organic encapsulation layer and an inorganic encapsulation layer.

The encapsulation layer 300 may include first and second inorganic encapsulation layers 310 and 330 and an organic encapsulation layer 320 interposed between the layers 310 and 330. The number of organic encapsulation layers, the number of inorganic encapsulation layers, and the order in which organic encapsulation layers and inorganic encapsulation layers are stacked may be configured according particular embodiments.

The first and second inorganic encapsulation layers 310 and 330 may include at least one inorganic insulating material, such as aluminum oxide, titanium oxide, tantalum oxide, hafnium oxide, zinc oxide, silicon oxide, silicon nitride, and/or silicon oxynitride, and may be formed via chemical vapor deposition (CVD) or the like. The organic encapsulation layer 320 may include a polymer-based material. Examples of the polymer-based material may include an acrylic resin, an epoxy-based resin, polyimide, and polyethylene.

Because the first inorganic encapsulation layer 310 is formed along structures below the first inorganic encapsulation layer 310, the upper surface of the first inorganic encapsulation layer 310 is not flat. The organic encapsulation layer 320 covers the first inorganic encapsulation layer 310 and may have a substantially flat upper surface that overlaps the organic light-emitting diode OLED, which is a display element. The organic encapsulation layer 320 may reduce a stress generated on the first and second inorganic encapsulation layers 310 and 330.

The organic encapsulation layer 320 may include polymethyl methacrylate (PMMA), polycarbonate (PC), polystyrene (PS), acryl-based resin, epoxy-based resin, polyimide, polyethylene, polyethylene sulfonate, polyoxymethylene, polyarylate, hexamethyldisiloxane, and/or the like.

The organic encapsulation layer 320 may include unit organic encapsulation layers 320u respectively overlapping the display units 200. The unit organic encapsulation layers 320u may be arranged on the islands 101 of the substrate 100, and may not be arranged on the connection units 102. The first inorganic encapsulation layer 310 and the second inorganic encapsulation layer 330 may contact each other outside the unit organic encapsulation layer 320u and may encapsulate the display units 200.

Since the encapsulation layer 300 includes the first inorganic encapsulation layer 310, the organic encapsulation layer 320, and the second inorganic encapsulation layer 330, even when the encapsulation layer 300 cracks, this crack may not penetrate the encapsulation layer 300 due to this multi-layered structure. Accordingly, formation of a path via which external moisture, oxygen, or the like infiltrates into the display units 200 may be prevented or minimized. The second inorganic encapsulation layer 330 may contact the first inorganic encapsulation layer 310 at an edge of the unit organic encapsulation layer 320u so that the unit organic encapsulation layer 320u may not be exposed to the outside.

Because the first inorganic encapsulation layer 310 and the second inorganic encapsulation layer 330 may be formed on the entire surface of the substrate 100 by chemical vapor deposition (CVD), the first inorganic encapsulation layer 310 and the second inorganic encapsulation layer 330 may be formed to cover lateral surfaces of the opening V.

When the unit organic encapsulation layer 320u is formed, a certain amount of liquid organic material is coated to correspond to the display unit 200 and is then cured. According to the characteristics of the liquid organic material, the liquid organic material flows toward an edge of the display unit 200. To prevent this, a dam structure (not shown) and/or a concave recess structure (not shown) may be further included in the edge of the display unit 200.

Wires WL for supplying signals and/or voltages to the display unit 200 may be arranged on/in the connection unit 102b of the substrate 100. Some wires WL may include the same material as that included in the source electrode SE or the drain electrode DE of the thin-film transistor TFT. Some wires WL may be formed on an organic material layer 202. Some wires WL may include the same material as that included in the gate electrode GE of the thin-film transistor TFT. Some wires WL may be included in/near the center of the connection unit 102b and may be spaced from one another.

The wires WL may be covered by the planarization layer 209. The first inorganic encapsulation layer 310 and the second inorganic encapsulation layer 330 may be stacked on the planarization layer 209. Because the first inorganic encapsulation layer 310 and the second inorganic encapsulation layer 330 are formed by using an open mask after the openings V is formed, the first inorganic encapsulation layer 310 and the second inorganic encapsulation layer 330 may surround the lateral surfaces of the openings V. The pixel defining layer 211 may be arranged between the planarization layer 209 and the first inorganic encapsulation layer 310.

Because the connection unit 102b of the substrate 100 may have a smaller width than the island 101, the connection unit 102b of the substrate 100 may be weak to a stress that is generated during deformation of the shape of the display apparatus. For preventing cracks from occurring in the wires WL arranged in the connection unit 102b, a neutral plane needs to be formed at the locations of the wires WL.

The pattern layers IPL (or insulating material member sets IPL) including an inorganic material and the organic material layer 202 covering the pattern layer IPL are introduced between the wires WL and the substrate 100 so that the neutral plane is formed in accordance with the locations of the wires WL.

The pattern layers IPL may be arranged at edges of the connection unit 102b and may not be overlapped by the wires WL. Because wires WL having a large modulus are not arranged at an edge region of the connection unit 102b, a location of the neutral plane at an edge portion of the connection unit 102b may be different from a location of the neutral plane at a center portion of the connection unit 102b. Without the pattern layers IPL, cracks may propagate to the wires WL due to a stress applied to the edge of the connection unit 102b.

The pattern layers IPL including an inorganic material having a similar modulus to the modulus of the wires WL is introduced into the edge of the connection unit 102b to compensate for the location of the neutral surface, thereby reducing a stress that may be applied to the wires WL.

The pattern layers IPL may include an inorganic insulating material, such as silicon oxide, silicon nitride, silicon oxynitride, aluminum oxide, titanium oxide, tantalum oxide, or hafnium oxide. The pattern layers IPL may include the same material as at least one of the buffer layer 201, the gate insulating layer 203, the first interlayer insulating layer 205, and the second interlayer insulating layer 207. The pattern layers IPL may be formed by forming and etching material layers for one or more of the buffer layer 201, the gate insulating layer 203, the first interlayer insulating layer 205, and the second interlayer insulating layer 207 on the connection unit 102b such that the pattern layers IPL and the corresponding ones of the buffer layer 201, the gate insulating layer 203, the first interlayer insulating layer 205, and the second interlayer insulating layer 207 remain on the substrate 100. The pattern layer IPL may be formed by depositing and etching a particular inorganic insulating material layer. Various pattern layers IPL may be implemented.

The organic material layer 202 may cover the pattern layers IPL, and the wires WL may be disposed on the organic material layer 202. Because the organic material layer 202 has lower hardness than an inorganic material, the organic material layer 202 absorbs a tensile stress generated due to deformation of the shape of the connection unit 102b and thus may minimize concentration of a stress on the wires WL. In addition, as the organic material layer 202 is disposed below the wires WL, a neutral plane may be disposed on the location of the wires WL. Moreover, the organic material layer 202 may prevent a difference between heights of the wires WL and the corresponding parts on the island 101 from occurring when the wires WL are connected to the island 101.

The organic material layer 202 may include an organic insulating material, such as polyimide, polyamide, acryl resin, benzocyclobutene, hexamethyldisiloxane (HMDSO), or phenol resin. The organic material layer 202 may be a single layer or multi-layer structure.

In FIG. 4, the pattern layer IPL is shown as being disposed closer to the connection unit 102b of the substrate 100 than to the wires WL, but the present invention is not limited thereto. The pattern layer IPL may be positioned farther from the connection unit 102b than the wires WL.

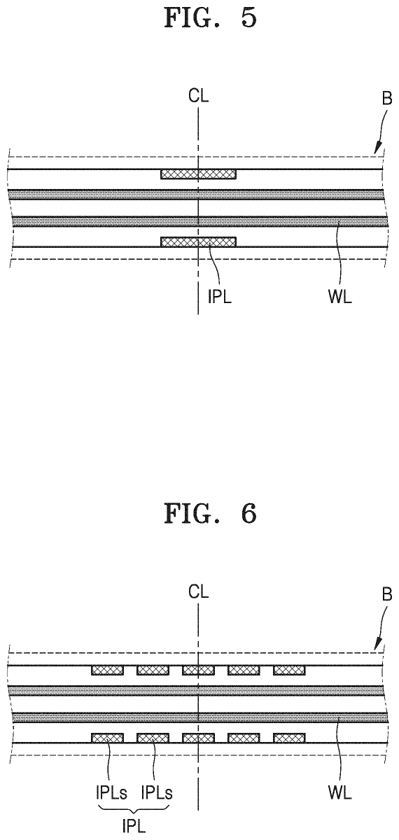

Each of FIGS. 5 through 8 is a schematic plan view of a connection unit according to an embodiment. Each of FIGS. 5 through 8 shows a region B of a connection unit 102 shown in FIG. 1.

Referring to FIG. 1, FIG. 3, and FIGS. 5 through 8, a connection unit 102a may have a rectangular shape having longer sides in a first direction X and shorter sides in a second direction Y. The connection unit 102a may extend lengthwise in the first direction X, and the wires WL may extend in the lengthwise direction of the connection unit 102a. The wires WL may be arranged between (and parallel to) the longer sides of the connection unit 102a. The pattern layers IPL may be arranged along the longer sides of the connection unit 102a. A connection unit 102b may be oriented substantially perpendicular to a connection unit 102a and may have features that are analogous to features of the connection unit 102a. The connection unit 102a may have features that are analogous to features of the connection unit 102b.

Referring to FIG. 5, the pattern layers IPL may be arranged at centers CL of the longer sides of the connection unit 102a. For example, the pattern layers IPL may overlap a geometric center line of the connection unit 102a that cross the longer sides of the connection unit 102a in the plan view of the display apparatus. The centers CL of the longer sides of the connection unit 102a may be where the greatest deformation of the substrate 100 occurs. As the pattern layers IPL are positioned at the centers CL of the longer sides, stress potentially applied to the wires WL may be effectively blocked. The pattern layers IPL may extend along two opposite edges of the connection unit 102a, respectively, and may be shorter than the wires WL in the lengthwise direction of the connection unit 102a (i.e., the first direction X). Each of the pattern layers IPL may have an island shape. The pattern layers IPL may be spaced from the wires WL in a plan view of the display apparatus and may not overlap the wires WL in the third direction Z (indicated in FIG. 2A).

Referring to FIG. 6, the pattern layers IPL may be arranged on two opposite edges of the connection unit 102a, and sub-patterns IPLs (or insulating material members IPLs) may be spaced from one another along each of the two opposite edges of the connection unit 102a. At least one of the sub-patterns IPLs may be arranged on the center CL of a longer side of the connection unit 102a. When the pattern layers IPL continuously extend along the longer sides of the connection unit 102a so as to adjust a neutral plane of the connection unit 102a, deformation of the connection unit 102a may be hindered by the pattern layers IPL. The sub-patterns IPLs spaced apart from one another may facilitate deformation of the connection unit 102a and may effectively adjust the neutral plane of the connection unit 102a. Each of the sub-patterns IPLs may have a rectangle shape and/or a different shape in a plan view of the display apparatus.

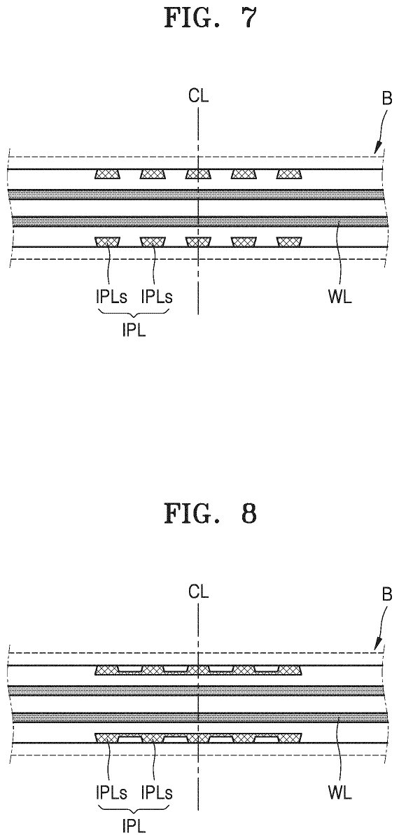

As shown in FIG. 7, each of the sub-patterns IPLs may have a shape that widens in an inward direction of the connection unit 102a toward the wires WL in a plan view of the display apparatus. Widths of each of the sub-patterns IPLs may increase from an edge of the connection unit 102a to the inside of the connection unit 102a. For example, each of the sub-patterns IPLs may have a trapezoidal shape. Accordingly, the location of the neutral plane may be more precisely adjusted.

Referring to FIG. 8, the sub-patterns IPLs may be connected to one another with a thin connection pattern/line (or an insulating material part) near the wires WL. In this case, when a stress is applied to the pattern layer IPL, the thin connection pattern/line may be easily disconnected to thereby facilitate deformation of the connection unit 102a.

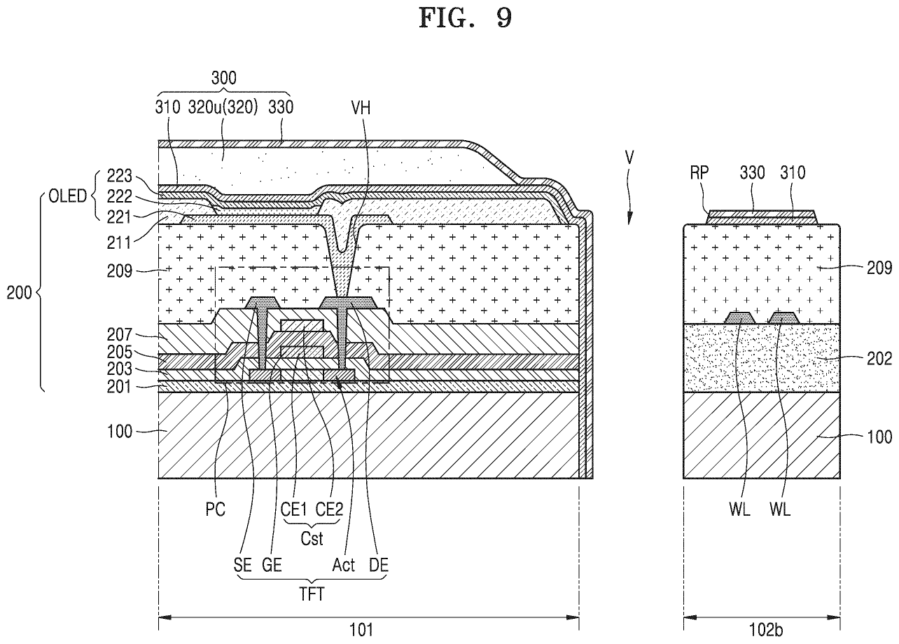

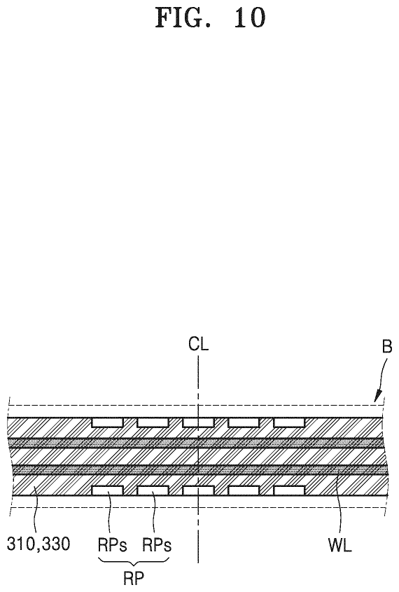

FIG. 9 is a schematic cross-sectional view of a display apparatus according to an embodiment. The same reference numerals in FIGS. 4 and 9 may denote identical or analogous elements.

Referring to FIG. 9, the display apparatus includes a substrate 100, a display unit 200 (including a portion of the planarization layer 209), and an encapsulation layer 300 covering the display unit 200.

As shown in FIGS. 1 through 3, the substrate 100 may include islands 101 spaced apart from one another, connection units 102 connecting the islands 101 to one another, and openings V penetrating through the substrate 100 and positioned between the connection units 102 and the islands 101.

The display units 200 may be disposed on the islands 101, respectively. The display unit 200 may include a group of display elements arranged on one island 101. The display unit 200 may include only one display element. The display unit 200 may include display elements having red, green, and blue colors.

A display element, for example, an organic light-emitting diode OLED, of the display unit 200 may be disposed on the planarization layer 209. The planarization layer 209 may provide a flat upper surface underlying the organic light-emitting diode OLED.

The encapsulation layer 300 may be disposed on the organic light-emitting diode OLED to protect the organic light-emitting diode OLED from ambient air. The encapsulation layer 300 may block external oxygen and external moisture and may include a single layer or a plurality of layers. The encapsulation layer 300 may include at least one of an organic encapsulation layer and an inorganic encapsulation layer.

Wires WL for supplying signals and/or voltages to the display unit 200 may be arranged on/in the connection unit 102b of the substrate 100. The organic material layer 202 may be disposed below the wires WL, and the planarization layer 209 may be disposed above/on the wires WL.

The opposite electrode 223, the first inorganic encapsulation layer 310, and the second inorganic encapsulation layer 330 may be stacked above/on the planarization layer 209.

Because the connection unit 102b of the substrate 100 may have a smaller width than the island 101, the connection unit 102b of the substrate 100 may be weak to a stress that is generated during deformation of the shape of the display apparatus. Accordingly, cracks may occur in the wires WL arranged in the connection unit 102b if no recess patterns RP (or recess structures RP or recess sets RP) are implemented to form a neutral plane at the locations of the wires WL.

Recess structures RP may be formed in the first inorganic encapsulation layer 310 and the second inorganic encapsulation layer 330 so that a neutral plane is formed in accordance with the locations of the wires WL. The recess structures RP may be formed by removing portions of the first inorganic encapsulation layer 310 and the second inorganic encapsulation layer 330 from the edge of the connection unit 102b.

The recess structures RP may be disposed on opposite edges of the connection unit 102b. The recess structures RP may be not overlapped the wires WL in the third direction Z (indicated in FIG. 2A). Because wires WL having a large modulus are not arranged on the edge regions of the connection unit 102b, a location of the neutral plane on the edge portions of the connection unit 102b may be different from a location of the neutral plane on the center portion of the connection unit 102b.

Due to formation of the recess structures RP, the same neutral plane may be formed on the center portion and the edge portions of the connection unit 102b, and thus stress that may be applied to the wires WL may be reduced.

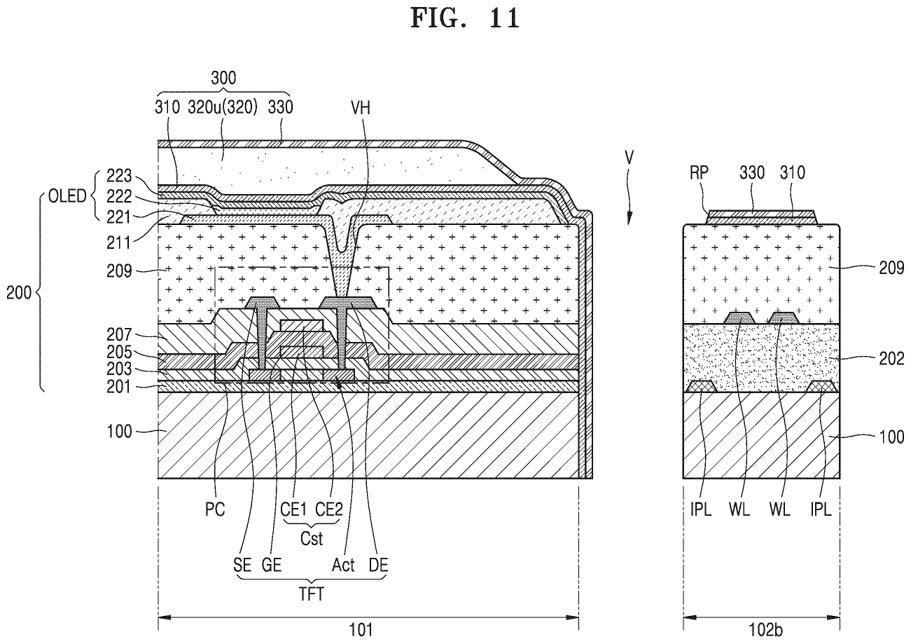

FIG. 10 is a schematic plan view of a connection unit according to an embodiment related to FIG. 9. FIG. 10 shows a region B of a connection unit shown in FIG. 1.

Referring to FIG. 1, FIG. 3, and FIG. 10, a connection unit 102a may have a rectangular shape having longer sides in a first direction X and shorter sides in a second direction Y. The connection unit 102a may extend lengthwise in the first direction X, and the wires WL may extend in the lengthwise direction of the connection unit 102a. The wires WL may be arranged between (and parallel to) the longer sides of the connection unit 102a.

The first inorganic encapsulation layer 310 and the second inorganic encapsulation layer 330 may cover all of the wires WL. The first inorganic encapsulation layer 310 and the second inorganic encapsulation layer 330 may include the recess structures RP formed by removing portions of the first inorganic encapsulation layer 310 and the second inorganic encapsulation layer 330 from the longer sides of the connection unit 102a. The recess structures RP may be disposed along the longer sides of the connection unit 102a.

As shown in FIG. 10, the recess structures RP may include sub-recesses RPs (or recesses RPs) spaced apart from each other along the longer sides of the connection unit 102a. At least one of the sub-recesses RPs may be arranged on the center CL of a longer side of the connection unit 102a. Instead of spaced sub-recesses RPs, a continuous recess structure RP may be provided at each longer side of the connection unit 102a. A recess structure RP may expose an entire longer side of the connection unit 102a. The recess structures RP and/or the sub-recesses RPs may include one or more of various shapes in a plan view of the display apparatus. A connection unit 102b may be oriented substantially perpendicular to a connection unit 102a and may have features that are analogous to features of the connection unit 102a. The connection unit 102a may have features that are analogous to features of the connection unit 102b.

FIG. 11 is a schematic cross-sectional view of a display apparatus according to an embodiment. The same reference numerals in FIGS. 4, 9, and 11 denote identical or analogous elements.

Referring to FIG. 11, the display apparatus includes a substrate 100, a display units 200 (including a portion of the planarization layer 209), and an encapsulation layer 300 covering of the display unit 200.

Wires WL for supplying signals and/or voltages to the display unit 200 may be arranged on/in the connection unit 102b of the substrate 100. The organic material layer 202 may be disposed below the wires WL, and the planarization layer 209 may be disposed above/on the wires WL. The opposite electrode 223, the first inorganic encapsulation layer 310, and the second inorganic encapsulation layer 330 may be stacked above/on the planarization layer 209.

Pattern layers IPL (or insulating material member sets IPL) may be disposed between the substrate 100 and the organic material layer 202 on the connection unit 102b, and recess structures RP may be included in the first inorganic encapsulation layer 310 and the second inorganic encapsulation layer 330.

The pattern layers IPL and the recess structures RP may compensate for the neutral plane of the connection unit 102b. The pattern layers IPL and the recess structures RP may overlap each other (in the third direction Z indicated in FIG. 2A).

The pattern layers IPL may be arranged along the longer sides of the connection unit 102b and may not overlap the wires WL in the third direction Z (indicated in FIG. 2A). The pattern layers IPL may include an inorganic insulating material, such as silicon oxide, silicon nitride, silicon oxynitride, aluminum oxide, titanium oxide, tantalum oxide, or hafnium oxide.

The recess structures RP may be formed by removing portions of the first inorganic encapsulation layer 310 and the second inorganic encapsulation layer 330 from the two longer sides of the connection unit 102b. The recess structures RP may be disposed along the two longer sides of the connection unit 102b. The recess pattern RP may not overlap the wires WL in the third direction Z (indicated in FIG. 2A).

According to embodiments, a flexible display apparatus such as a stretchable display apparatus with high reliability may be implemented.

The described embodiments should be considered in an illustrative sense and not for purposes of limitation. Descriptions of features or aspects within each embodiment should typically be considered as available for other similar features or aspects in other embodiments. While embodiments have been described with reference to the figures, various changes in form and details may be made in the described embodiments without departing from the scope defined by the following claims.

What is claimed is:

1. A display apparatus comprising:
a substrate comprising a first island, a connection unit, a second island spaced from the first island and connected through the connection unit to the first island, and an opening positioned between the connection unit and the first island;
a first display unit overlapping the first islands;
a second display unit overlapping the second island;
a conductive wire overlapping the connection unit; and
an insulating material member set overlapping an edge region of the connection unit, positioned closer to or farther from the connection unit than the conductive wire, and spaced from the conductive wire in a plan view of the display apparatus.

2. The display apparatus of claim 1, wherein the insulating material member set includes an inorganic insulating material.

3. The display apparatus of claim 1, further comprising an organic material layer disposed between the insulating material member set and the conductive wire.

4. The display apparatus of claim 1, further comprising a buffer layer, a gate insulating layer, a first interlayer insulating layer, and a second interlayer insulating layer each including an inorganic insulating material and disposed on the first island, wherein a material of the insulating material member set is identical to a material of at least one of the buffer layer, the gate insulating layer, the first interlayer insulating layer, and the second interlayer insulating layer.

5. The display apparatus of claim 1, wherein a first side of the connection unit is longer than a second side of the connection unit, and wherein the insulating material member set overlaps a geometric center line of the connection unit that cross the first side of the connection unit in the plan view of the display apparatus.

6. The display apparatus of claim 1, wherein the insulating material member set comprises insulating material members that are spaced from one another in a lengthwise direction of the connection unit.

7. The display apparatus of claim 6, wherein the insulating material members include a first insulating material member, and wherein a first edge of the first insulating material member is longer than a second edge of the first insulating material member, opposite the second edge of the first insulating material member, and positioned between the conductive wire and the second edge of the first insulating material member in the plan view of the display apparatus.

8. The display apparatus of claim 6, wherein the insulating material member set comprises an insulating material part, wherein two of the insulating material members are connected through the insulating material part to each other, wherein a space is positioned between the two of the insulating material members, and wherein the insulating material part is positioned between the conductive wire and the space.

9. The display apparatus of claim 1, further comprising an encapsulation layer covering the first display unit, wherein the encapsulation layer comprises an organic encapsulation layer, a first inorganic encapsulation layer, and a second inorganic encapsulation layer, wherein the organic encapsulation layer is positioned between the first inorganic encapsulation layer and the second inorganic encapsulation layer and is spaced from the connection unit by at least one of the first inorganic encapsulation layer and the second inorganic encapsulation layer, and wherein the first inorganic encapsulation layer and the second inorganic encapsulation layer directly contact each other outside the organic encapsulation layer.

10. The display apparatus of claim 9, wherein the first inorganic encapsulation layer and the second inorganic encapsulation layer directly contact each other on the connection unit.

11. The display apparatus of claim 10, wherein the first inorganic encapsulation layer and the second inorganic encapsulation layer comprise a recess set that overlaps with the edge region of the connection unit.

12. The display apparatus of claim 11, wherein the recess set comprises recesses that are spaced from each other in a lengthwise direction of the connection unit.

13. A display apparatus comprising:
a substrate comprising a first island, a connection unit, a second island spaced from the first island and connected through the connection unit to the first island, and an opening positioned between the connection unit and the first island;
a first display unit overlapping the first island;
a second display unit overlapping the second island;
an encapsulation layer covering the first display unit and comprising a first inorganic encapsulation layer, an organic encapsulation layer, and a second inorganic encapsulation layer; and
a conductive wire overlapping the connection unit,
wherein the first inorganic encapsulation layer and the second inorganic encapsulation layer directly contact each other on the connection unit and comprise a recess set, and wherein the recess set overlaps with an edge region of the connection unit and is spaced from the conductive wire in a plan view of the display apparatus.

14. The display apparatus of claim 13, wherein the recess set comprises recesses that are spaced from each other in a lengthwise direction of the connection unit.

15. The display apparatus of claim 13, further comprising an organic material layer disposed between the conductive wire and the connection unit.

16. The display apparatus of claim 13, wherein the organic encapsulation layer overlaps the first display unit and is spaced from the connection unit by at least one of the first inorganic encapsulation layer and the second inorganic encapsulation layer, and wherein the first inorganic encapsulation layer and the second inorganic encapsulation layer directly contact each other outside the organic encapsulation layer.

17. The display apparatus of claim 13, wherein the first inorganic encapsulation layer and the second inorganic encapsulation layer directly contact lateral surfaces of the opening.

18. The display apparatus of claim 13, further comprising an insulating material member set, wherein the insulating material member set is positioned closer to or farther from the connection unit than the conductive wire, overlaps the edge region of the connection unit, and is spaced from the conductive wire in the plan view of the display apparatus.

19. The display apparatus of claim 18, wherein the insulating material member set includes an inorganic insulating material.

20. The display apparatus of claim 18, wherein the recess set overlaps with the insulating material member set.
